(19) United States
(12) Patent Application Publication
(10) Pub. No.: US 2025/0300146 A1
(43) Pub. Date: Sep. 25, 2025

(54) Extremely Large Area Integrated Circuit

(71) Applicant: Massachusetts Institute of Technology, Cambridge, MA (US)

(72) Inventors: Kenneth Schultz, Lexington, MA (US); Brian Tyrrell, Madison, AL (US); Rabindra Das, Lexington, MA (US)

(21) Appl. No.: 18/863,233

(22) PCT Filed: Mar. 9, 2023
(86) PCT No.: PCT/US2023/014893

§ 371 Date: Nov. 5, 2024

Related U.S. Application Data
(60) Provisional application No. 63/344,705, filed on May 23, 2022.

(51) Int. Cl. H01L 25/16

(52) U.S. Cl. CPC H01L 25/167

(57) ABSTRACT

Extremely Large Area Integrated Circuits (ELAIC) may become an attractive tiling method for 2D integration to meet the demands of higher functionality in ever smaller packages, especially when coupled with the use of heterogeneous chips. This new tiling solution is suitable for combining multiple memory, ASICs, CPU, GPU, etc., into a single package. This approach also favors system integration with high density power delivery by appropriate build-up materials, design and thermal management. ELAIC technology with bare multi-die integration offers a number of advantages relative to the equivalent integration methods.

This application claims priority to U.S. Provisional Patent Application Ser. No. 63/344,705, filed May 23, 2022, the disclosure of which is herein incorporated by reference in its entirety.

This invention was made with government support under FA8702-15-D-0001 awarded by the U.S. Air Force. The government has certain rights in the invention

### BACKGROUND

The increasing demand for digital transformation, computing, mobility, and connectivity is driving the microelectronics industry toward cost driven, convergent, miniaturized technology with increased performance and lower power consumption to bring more and more applications into next generation devices. Over the last decade, high performance computing has evolved to adapt smaller and more diverse technology nodes suitable for the artificial intelligence (AI), machine learning and greater embedded computing platforms. These applications are consistently forced to compromise between enabling more compute capability and the constraints of volume and weight which can be dedicated to computation, along with the associated thermal dissipation and power. Most of the power consumption for the above applications is due to moving data between chips in a system rather than the actual computing. Furthermore, the traditional Moore's Law for developing next-generation devices has forced the microelectronics industry to develop alternative advanced packaging architectures and heterogeneous integration technology. New packaging architectures need to integrate multiple processor and accelerator chips with minimum chip-to-chip the spacing to minimize interconnect length, on-chip memory, higher bandwidth connection, and greater heat densities, while being pushed into higher I/O counts, smaller pitches, and larger footprints. In addition, new advanced packaging requires mixed material, and versatile construction to accommodate the complexity associated with size, weight and power (SWaP) optimization.

Traditionally, greater wiring densities are achieved by reducing the dimensions of vias, lines, and spaces, increasing the number of wiring layers, and utilizing blind and buried vias. However, each of these approaches possesses inherent limitations. For example, some of the limitations are related to drilling and plating of high aspect ratio vias, reduced conductance of narrow circuit lines, and increased cost of fabrication related to additional wiring layers. As a result, the microelectronics industry is moving toward alternative, innovative approaches to create solutions for squeezing more functionality into smaller packages. Assembly and packaging are bridging the gap by enabling economic use of the third dimension (3D packaging). System level integration is emerging. These approaches include System-in-Package (SiP), stacked die, or package stacking solutions. In addition to the trend toward miniaturization, new materials and structures are required to keep pace with more demanding packaging performance requirements. Wafer level package (WLP) and panel level package (PLP) have become the preferred method for lower cost integration to meet the demands of higher functionality in ever smaller packages, especially when coupled with the use of different technology node dies. However, WLP has some major limitations. The size of WLP increases with smaller technology nodes and causes more reliability and chip package interaction (CPI) challenges. Today, various technologies including wafer-level chip-size packages (WL CSPs), Fan-out wafer-level packages, wafer capping and thin film capping on MEMS devices, wafer-level packages with Through Silicon Vias (TSVs), wafer-level packages with Integrated Passive Devices (IPD), and wafer-level substrates featuring fine traces and embedded integrated passives are considered to be WLP.

Therefore, an improved system and method for integrating heterogeneous dies into a single package is needed.

### SUMMARY

Extremely Large Area Integrated Circuits (ELAIC) are an attractive tiling method for 2D integration to meet the demands of higher functionality in ever smaller packages, especially when coupled with the use of heterogeneous chips. This new tiling solution is suitable for combining multiple memory, ASICS, CPU, GPU, and other components into a single package. This approach also favors system integration with high density power delivery by appropriate build-up materials, design and thermal management. ELAIC technology with bare multi-die integration offers a number of advantages relative to the equivalent integration methods:
combining known good chips together to make systems that perform like an extremely large single heterogeneous chip for reducing latency and increasing efficiency of a system.
Combine different thickness, different foundry processed known good chips to produce an extremely large single heterogeneous artificial chip with chip like wiring density
Provide close-packed chip assembly with 0-20 μm separation between chips
Provide >99% Si chip content and <1% gap fill material content
Provide chip like inter-chip planarity.
Achieve up to 99% chip area in ELAIC platform.
Include plated metal (e.g., Cu) and/or alloy based inter-chip gap fill to create a built-in heat-sink for efficient heat-dissipation.
Post process Chip-to-chip alignment of 0-3 μm with efficient alignment correction capability using industry standard lithography approach as well as a new approach including image transfer to make a digital mask.
Use silicon and/or optically flat substrate lamination approach to achieve chip like inter-chip planarity, Plasma diced chip will provide narrowest gap between chips and one of the best solutions to create ELAIC from known good chips.
Plasma diced and/or laser diced chip can create inter-lock chip architecture to minimize and/or eliminate chip-to-chip misalignment

### BRIEF DESCRIPTION OF THE DRAWINGS

For a better understanding of the present disclosure, reference is made to the accompanying drawings, in which like elements are referenced with like numerals, and in which:

FIG. 1A shows the prior art;

FIG. 1B shows the ELAIC concept;

FIG. 1C shows the ELAIC open interface for die based systems;

FIG. 1D shows embodiments of the ELAIC having different numbers of chips;

FIGS. 2A-2F show the general process to create an ELAIC;

FIGS. 3A-3H show a first representative fabrication process that may be utilized to create an ELAIC;

FIGS. 4A-4G show a second representative fabrication process that may be utilized to create an ELAIC;

FIGS. 5A-5F show a third representative fabrication process that may be utilized to create an ELAIC;

FIG. 6 shows a comparison of the face down approach and the face up approach;

FIG. 7 shows the integration of processors, accelerators, memory and other components using ELAIC;

FIG. 8 shows 3D integration with ELAIC and a photonic integrated circuit and/or an electronic integrated circuit;

FIG. 9 shows the ELAIC of FIG. 8 connected with optical fibers;

FIG. 10 shows a cross-section of the structure shown in FIG. 8 according to one embodiment;

FIG. 11 shows a cross-section of the structure shown in FIG. 8 according to a second embodiment; and

FIG. 12 shows a cross-section of the structure shown in FIG. 8 according to a third embodiment.

### DETAILED DESCRIPTION

Large-area integrated circuits are used in many applications, including mission-critical Department of Defense systems. Examples of these systems include conventional high-performance computing, superconducting classical and quantum computing, large format digital focal plane arrays (DFPAs) for wide area infrared search and track, photonic integrated circuit tiling, and phased-array radars up to millimeter wave.

Integration of multiple chips that were produced using different (heterogeneous) fabrication technologies has been a persistent challenge. Typically, individually packaged chips use a board-level assembly approach, and the associated “parasitic” electrical overhead and latency become the limiting factors to a system's performance. This disclosure presents an inventive Extremely Large Area Integrated Circuit (ELAIC) that addresses this need while overcoming many of the shortcomings of the prior art.

Specifically, this disclosure describes a novel “Extremely Large Area Integrated Circuit (ELAIC)” and a method for extending packaging performance beyond the limits imposed by traditional wafer level packaging (WLP) approaches. In the ELAIC structure, multiple known good dies (chips) are attached with build-up/re-distributions layers (RDL) instead of flip-chip integration, and maintain finer lines and spaces to achieve high density circuits. The build-up layer will not only increase circuit density but also improves package stability and reliability by increasing Si content, minimizing organic materials and reducing mixed materials, as well as low/high CTE impacts.

The ELAIC integration process will allow the tiling of known good dies to make systems that perform as a single-chip monolithic device, despite being composed of several smaller heterogeneous dies. This approach differs from other research technology platforms in many ways and is working to ensure cryogenic compatibility of the process (desirable for a large number of future application areas).

For convenience, certain introductory concepts and terms used in the specification are defined here.

As used herein, the term “extremely large area integrated circuit (also known as ELAIC)” is used to describe a novel, heterogeneous chip tiling that enables the development of highly secured, extremely large-area integrated circuits (ELAICs) with multiple (from few to hundreds) closely spaced small chips (called chiplets) fabricated via a lithographic process (which may be, for example, 2-, 5-, 7-, or 10-nanometer). These ELAICs address the increasing size and performance demands made on microelectronics used in mobile devices, complex sensing systems, high-performance computing, and the automotive, healthcare, and aerospace industries. The ELAICs are capable of combining a large number (e.g., 4, 9, 16, 20, 25, 40, 80, 100, 256 or more) of chiplets together to make energy efficient systems that perform like a heterogeneous single chip with chip-like wiring, chip-like Si content, chip-like inter-chip planarity and very narrow (0-20 μm) inter-chip spacing enabling small (20-100 μm) interconnects and I/O pitch for chip-to-chip communication. The small interconnect provides support for parallel interfaces and eliminates the need for serializers and deserializers (SerDes). The small I/O pitch provides support for high data bandwidth using a parallel interface. By integrating multiple chiplets into one large-area chip (2D array), the ELAIC approach can help solve two challenges to the microelectronics industry: expanding the yield of chip manufacture and reducing both cost and time to develop systems. The ELAIC approach increases AI system performance and compute density by integrating multi-core chiplets, enabling chip level connectivity between GPUs, FPGAs and AI accelerators to accelerate AI training workload. The ELAIC with memory close to processor helps to reduce latency for real-time processing and reduce energy cost of data movement. A large memory with high memory bandwidth to match compute throughput supports voluminous amount of data processing for AI engine (Deep Neural Network). The highly efficient ELAIC interface enables connectivity between a wide variety of components.

As used here, the term “chemically activated surface” is used to describe a surface which is minimally etched and/or damaged. The hydrophilicity or hydrophobicity of the surface may be changed using an appropriate plasma and/or chemical treatment by changing or modifying the surface chemistry.

As used herein, the term “circuitized substrate” is used to describe a semiconductor structure including at least one dielectric layer, the at least one dielectric layer having at least one surface on which at least one circuit is disposed. Examples of dielectric materials suitable for the at least one dielectric layer include low temperature co-fired ceramic (LTCC), ceramic (alumina), fiberglass-reinforced or non-reinforced epoxy resins (sometimes referred to simply as FR4 material, meaning its Flame Retardant rating), poly-tetrafluoroethylene (Teflon), polyimides, polyamides, cyanate resins, photoimagable materials, and other like materials, or combinations thereof. Examples of electrically conductive materials suitable for the at least one circuit include copper and copper alloy. If the dielectric layer is provided from a photoimagable material, it is photoimaged or photopatterned, and developed to reveal the desired circuit pattern, including the desired opening(s) as defined herein, if required. The dielectric layer may be curtain coated or screen applied, or it may be supplied as a dry film or in other sheet form.

As used herein, the term “conductive fusible metal” is used to describe a metal including one or more of tin-lead, bismuth-tin, bismuth-tin-iron, tin, indium, tin-indium, indium-gold, tin-indium-gold, tin-silver, tin-gold, indium, tin-silver-zinc, tin-silver-zinc-copper, tin-bismuth-silver, tin-copper, tin-copper-silver, tin-indium-silver, tin-antimony, tin-zinc, tin-zinc-indium, copper-based solders, and alloys thereof. The metals may change forms (e.g., from a solid to a liquid) during a bonding or during post bonding annealing or reflow process.

As used herein, the term “conductive structure” is used to describe an interconnect structure for electrically coupling one or more interconnect pads, electrical connections, components, devices, modules, and semiconductor structures and devices. The conductive structure may include at least one of a micro via having a diameter which is between about one micrometer (μm) and about one-hundred fifty μm and a sub-micron via having a diameter of less than about one μm.

As used herein, the terms “chip”, “die” and “chiplet” are used interchangeably to describe a single or multilayer structure including a number of active or passive semiconductor and/or superconductor and/or optical and/or photonic components, the structure capable of performing at least part of the functional operations (i.e., semiconductor system performance) of a semiconductor structure. Device layers are typically fabricated separately on Silicon on insulator (SOI) substrates or bulk Silicon (Si) or Sapphire or Silicon carbide or GaAs or related substrates. Additionally, each device layer may include at least one interconnect and one or more of active Si, Germanium, Gallium nitride (GaN) and III-V field-effect transistors (FETs). These terms are also used to describe an integrated circuit that has not been packaged.

As used herein, the term “semiconductor package pitch” is used to define the distance (center-to-center) between pads and/or vias and/or traces. Package pitch can be same and/or different within a chip and between the chips.

As used herein, the term “integrated circuit (IC)” is used to describe an electronic device (such as a semiconductor chip, optical chip, photonic chip, superconductor chip or a combination thereof).

As used herein, the term “interposer” is used to describe an interconnect structure capable of electrically coupling two or more semiconductor structures together.

As used herein, the term “semiconductor structure” is used to describe an integrated circuit, which may be packaged or may not be packaged. Thus, a die is one type of a semiconductor structure. Similarly, flip-chip die, photonic circuits, and traditional ICs are also semiconductor structures. Further, interposers are also semiconductor structures.

As used herein, the term “module” is used to describe an electrical component having a substrate (such as a silicon substrate or printed circuit board (PCB)) on which at least one semiconductor device is disposed. The module may include a plurality of conductive leads adapted for coupling the module to electrical circuitry and/or electrical components located externally of the module. One known example of such a module is a Multi-Chip Module (MCM), such modules coming in a variety of shapes and forms. These can range from pre-packaged chips on a PCB (to mimic the package footprint of an existing chip package) to fully custom chip packages integrating many chips on a High Density Interconnection (HDI) substrate.

As used herein, the term “processor” is used to describe an electronic circuit that performs a function, an operation, or a sequence of operations. The function, operation, or sequence of operations can be hard coded into the electronic circuit or soft coded by way of instructions held in a memory device. A processor may perform the function, operation, or sequence of operations using digital values or using analog signals. In some embodiments, the processor may be embodied, for example, in a specially programmed microprocessor, a digital signal processor (DSP), or an application specific integrated circuit (ASIC), which can be an analog ASIC or a digital ASIC. Additionally, in some embodiments the processor may be embodied in configurable hardware such as field programmable gate arrays (FPGAs) or programmable logic arrays (PLAs). In some embodiments, the processor may also be embodied in a microprocessor with associated program memory. Furthermore, in some embodiments the processor may be embodied in a discrete electronic circuit, which can be an analog circuit or digital circuit. Different types of processors are also described, including central processing units (CPUs) and graphic processing units (GPUS).

As used herein, the term “self-bondable oxide” is used to describe multilayer oxide (e.g., single or multi component, doped or undoped, high density-low density, and others), the multilayer oxide having at least one chemically activated, ultra-smooth bonding surface (e.g., having a roughness within a predetermined number of angstroms (Å)) capable of bonding with another self-bondable oxide without any external force. The process for bonding a first self-bondable oxide with a second self-bondable oxide requires minimum force to activate bonding at a symmetry point on a bonding surface of the first and second self-bondable oxides (e.g., wafers), and little to no additional force to self-propagate bonding to entire surfaces of the first and second self-bondable oxides. Self-bondable oxides preferably use an oxidizing-reducing agent to chemically activate a bonding surface. RCA cleaning procedures (e.g., RCA-1 clean, RCA-2 clean) and/or high frequency (HF) and/or mega sonic cleaning and/or Plasma (e.g., oxygen) and/or Ammonium Hydroxide may be used for pre-bond surface treatments for the self-bondable oxide. Additionally, annealing the self-bondable oxide at a temperature between about one-hundred fifty degrees Celsius (C) and about five-hundred degrees C. in presence of Hydrogen (H) or Nitrogen (N) may increase bond strength of the self-bondable oxide.

As used herein, the term “substrate” is used to describe any structure upon which an integrated circuit or semiconductor device may be disposed or upon which semiconductor materials may be deposited and/or into which semiconductor materials may be implanted and diffused to form a semiconductor structure or device. In some embodiments, the substrate may be provided as a P-type substrate having a particular range of concentrations of P-type atoms. In other embodiments, an N-type substrate may be used (i.e., a substrate having a particular range of concentration of N-type atoms).

The substrate may, for example, be provided from a semiconductor material, an insulator material or even a conductor material. For example, the substrate may be provided from silicon, alumina, glass or any other semiconductor material. Further, the substrate can include a number of metal-oxide-silicon (MOS) devices, complementary-MOS (CMOS) devices, or a number of active or passive integrated circuit semiconductor devices.

As used herein, the term “three-dimensional (3-D) integrated circuit (IC)” is used to describe a semiconductor structure which includes at least two device layers, which are vertically stacked and interconnects (e.g., vertical interconnects) to make one or more electrical connections between the device layers.

As used herein, the term “through oxide via (TOV)” is used to describe a via (e.g., micro via) in a semiconductor structure used to connect adjacent device layers. The TOV passes through one or more oxide, dielectric, and/or metal layers and terminates at a predetermined Silicon (Si) layer or surface.

As used herein, the term “via first” is used to describe a micro via and/or a submicro via used to make at least one electrical connection between a first device layer and second device layer in a semiconductor structure including at least two device layers. Additionally, as described here, the term “via first” may also be used to describe a micro via and/or a submicro via passing through a dielectric material or layer (in some embodiments, only the dielectric material or layer) to make at least one electrical connection between a first device layer and a second device layer in a semiconductor structure including at least two device layers. For a via first process, the first device layer and the second device layer are completed separately. As one example, a partial via material is added on first and/or second opposing surfaces (i.e., top and/or bottom surfaces) of the first and second device layers and subsequent bonding and/or post bonding process create a via first between the first and second device layers.

The via first may be filled with at least one metal or alloy having a high Coefficient of Thermal Expansion (CTE) to produce a rigid, robust, and conductive via first joint between the at least two device layers during the composite bonding process. High temperatures and/or high pressures may be applied and used to bond the two device layers and provide a three-dimensional (3D) interconnection (i.e., interconnect) among the device layers. The high CTE metal or alloy are expanded at relatively high temperatures and inter-diffuse with each other to produce the 3D interconnect. Alternatively, the via first may be filled with a low temperature fusible metal which melts and inter-diffuse during bonding or post bonding processes.

As used herein, the term “via last” is used to describe a micro via and/or a submicro via used to make at least one electrical connection between a first device layer and a second device layer in a semiconductor structure including at least two device layers. Fabrication of the first device layer is completed first, and the second device layer is deposited over the first device layer. The second device layer is completed with via last process. A pad layer which includes one or more interconnect pads may be added after via last process. In one embodiment, via last is filled. Additionally, in one embodiment, the via last can be unfilled or partially filled. Via last may pass through the device layers (e.g., second device layers) and, in some embodiments, one or more isolation layers or materials. A titanium (Ti) material having a thickness of about ten nanometers (nm) and, a metal organic chemical vapor deposition (MOCVD) Titanium Nitride (TiN) liner having a thickness of about five nm, and tungsten plugs may be used for via lasts. A MOCVD or chemical vapor deposition (CVD) TiNₓ, with X less than or equal to 1, is preferred for better conformal coating.

As used herein, the term “system on a chip” or “system on chip” (SoC or SOC) is used to describe an integrated circuit (IC) which integrates substantially all components of a computer or other system into a single chip. It may contain digital, analog, mixed-signal, and often radio-frequency functions-all on a single chip substrate. SOC with silicon-on-insulator can provide increased clock speeds while reducing power consumed by the chip.

A multiprocessor System-on-Chip (MPSOC) is a system-on-a-chip (SoC) which utilizes multiple processors, usually targeted for embedded applications. It is used by platforms that contain multiple, usually heterogeneous, processing elements with specific functionalities reflecting the need of the expected application domain, a memory hierarchy (often using scratchpad RAM and DMA) and I/O components. All these components are linked to each other using an on-chip interconnect. Multi die SoCs convert single die SoC into multiple dies. A micro-bump allows on-chip interconnects to be extended to a bridge between chips while allowing other signals to be integrated in a low power manner. Multi die SoCs can be approached differently. Multi-Die SoCs can have a large die having pads to interconnect with other dies to complete the SoC. The larger die can be relatively easy to fabricate and/or can have minimum yield impact. The larger die can be bumped to create an interconnect for flip-chip bonding with other dies to complete a multi-die SoC. It is further possible that a bumped die may be bonded to the larger die to complete the Soc. It is further possible to attach multiple dies to the larger die by flip-chip bonding as well as wire bonding techniques to complete the SoC.

A multi-die SoC may be coupled to a printed circuit board (PCB) and/or substrate by wire bonding. Several non-limiting coupling options are described below. These options include:
1. Single or multiple dies of SoC may be bumped to couple one or more components to a semiconductor structure (e.g., a die), and to create a multi-die SoC. In general, a larger component die which is relatively easy to fabricate will be used for bumping. These kinds of multi dies may prefer to use wirebonding in some embodiments. Alternatively, a larger component die may need to have at least one through via for flip-chip attachment.
2. An organic, ceramic, Si based interposer may be used to couple one or more semiconductor structures to the SoC and to create a multi-die SoC.
3. A Si based MCM may be used to couple one or more semiconductor structures to the SoC and to create a multi-die SoC.

As used herein, the term “Redistribution layer (RDL)”, also known as “build-up layer” is used to describe metal (e.g., Au, Cu, Au and others) and/or alloy based interconnects that electrically connect one part of the chiplet to another. ELAIC RDLs are measured by line and space. In one example, ELAIC RDLs may have minimum 1-5 μm line/space. For oxide based dielectric, ELAIC RDLs may have minimum 0.35-2 μm line/space. ELAIC RDL is useful for parallel I/Os. Additionally, this wiring metal layer with micro vias redistributes the I/O access to different parts of the chip and makes it easier to add microbumps to an ELAIC.

As used herein, the term “heterogeneous die” is used to describe same and/or different functionality die, fabricated on same and/or different type wafer (e.g., Si, SiC, GaAs, sapphire etc.).

As used herein, the term “parallel I/O (also known as parallel input/output)” is used to describe sets of I/O that perform multiple input/output computing operations simultaneously or sets of I/O that perform multiple input/output computing operations at the same time that allows groups of data bits to be transmitted simultaneously.

As used herein, the term “SerDes (also known as Serializer/Deserializer)” is used to describe a pair of functional blocks commonly used in high speed communications to compensate for limited input/output. A SerDes is an IP block of a chiplet or a full chip transceiver that converts parallel data to serial data and vice-versa. The transmitter section is a parallel-to-serial converter, and the receiver section is a serial-to-parallel converter.

As used herein, the term “Si-less bridge” is used to define a die that interconnects two neighboring chips using bump bonding and/or oxide bonding. Die use oxide coated (e.g., thermal oxide) silicon. Dies typically have single or multi-layer active and/or passive circuits. In one example, circuit thickness including oxide layer ranges from 2-6 micron. The bump bonded die underfilled (if necessary) and/or oxide-oxide bonded die, are used to create a Si-less bridge by removing the silicon and stopping at the oxide layer of die to create 2-6 micron thick active and/or passive circuits. In one example, Si-less bridge has a height of 2-6 micron without micro-bumps. This bump-bonded flip-chip die creates an interconnection bridge between the neighboring chips for chip-to-chip communication. Removing the silicon from a bridge die creates a Si-less bridge. The advantage of a Si-less bridge is that the added 2-6 micron height is negligible for next level of bump, C4 (controlled collapse chip connection) and/or BGA (ball grid array) connection. It is also possible to have very thin layer of Si (less than 50 um) on top of the oxide. In one example, Si removal was used, such as by grinding and/or polishing and/or wet etching and/or dry etching process. In another example, the Si-less die can have through oxide via (TOV) for further interconnection.

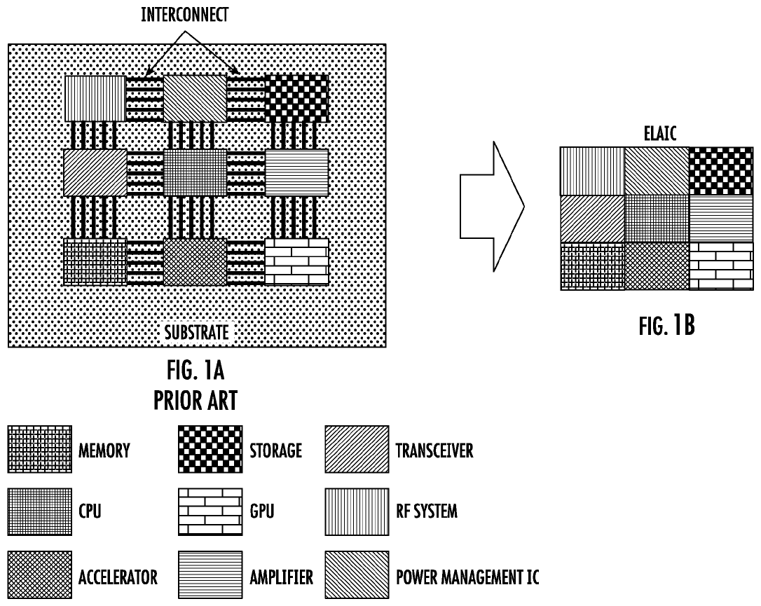

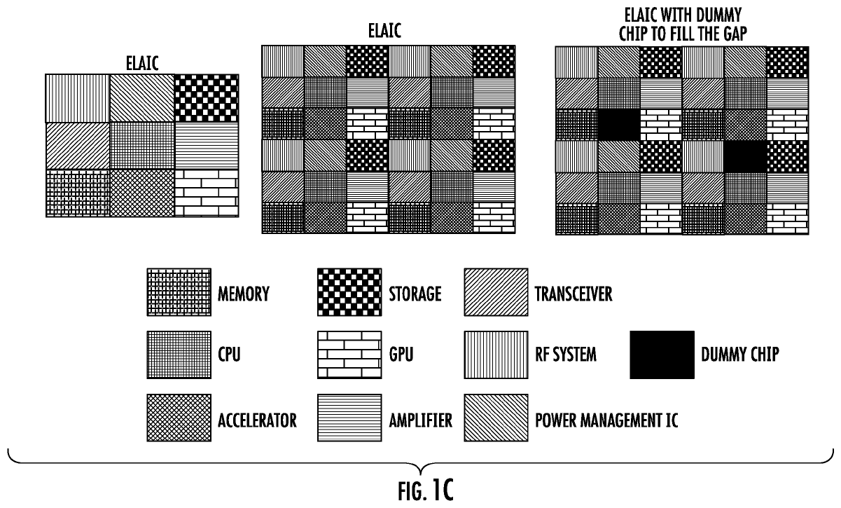

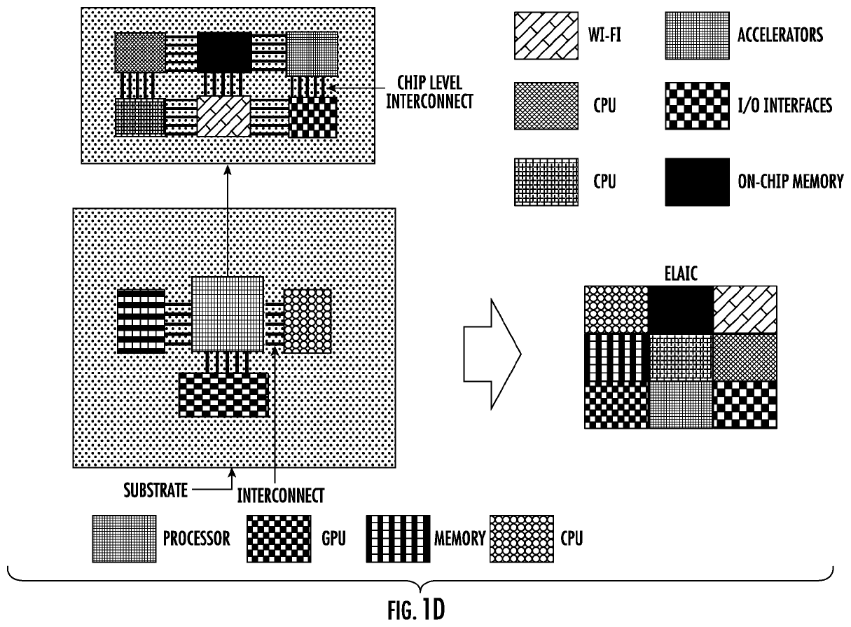

One objective is to develop a novel embedded chip packaging with built-in MCM (multi-chip modules) without Si capability that integrates very-large-scale integrated circuits (ICs) with 100s of superconducting and/or semiconductor and/or photonic and/or optical chips in proximity to one another, along with auxiliary semiconductor electronics (e.g., power supplies, clock generators, output amplifiers) in a single system, as shown in FIGS. 1A-1D.

FIG. 1A shows the prior art. This figure shows a traditional system where individual chips are attached to the substrate (organic or silicon) and interconnected with each other through the substrate. Typically, individually packaged chips use a board-level assembly approach, and the associated “parasitic” electrical overhead and latency become the limiting factors to a system's performance. FIG. 1B shows the ELAIC concept wherein all the dies are combined together where each individual die will have at least two nearest dies for interconnection. ELAIC creates chip like wiring and eliminates the need for a substrate. FIG. 1C shows an example of ELAIC scalability. It is noted that the number of dies is not limited by this disclosure. The left side of FIG. 1C shows an ELAIC made up of 9 dies, which may be any combination of CPUs, memories, accelerators (such as graphic accelerators), GPUS (graphic processing units), transceivers, amplifiers, RF systems, power management circuits and storage. The middle of FIG. 1C shows an ELAIC that is made up of 25 dies. The right side of FIG. 1C shows an ELAIC that is made up of 36 dies. Note that it is not necessary that the number of dies must match the product of the number of rows and the number of columns. For example, as shown in the right side of FIG. 1C, dummy chips may be used to fill empty spaces. Additionally, the dummy chip may also be used to compensate size difference between the chips to minimize the chip-to-chip gap. In some cases when chip thickness varies significantly (e.g., 50-500 micron), a thinner chip may be placed on top of dummy chip to minimize the chip thickness variation.

FIG. 1D shows an open interface for chiplet based designs. An important element in allowing separate dies on an ELAIC to function together as if they are on the same chip is the improvement of the data rates. An important key for an Open BLAIC design is creating an open interface, including a switch fabric interconnect to connect the Logic Blocks inside device, as shown in FIG. 1D. The figure shows how this is done with a network flow processor (NFP) and a communications layer protocol, similar to the OSI networking model. The ELAIC RDL can replace a lower connection density organic package (like a PCB) or a higher connection density silicon interposer. The left image of FIG. 1D shows a traditional assembly where multiple known good die, such as processor, GPU, CPU and memory (e.g., DRAM, NOR, NAND) are interconnected through the substrate. In one embodiment, a copper based interconnect with minimum line width ranging from 10 micron to 75 microns is used. In one example, the processor architecture shows individual IP blocks (e.g., on chip memory, CPU, accelerator, WI-FI, I/O Interface, etc.) used chip level interconnection (minimum line width sub-micron to micron range), in the right image of FIG. 1D shows the ELAIC configuration where individual IP blocks (chiplets) are used instead of processor chips to provide chip level ELAIC interconnection for chiplet-to-chiplet communication. In one example, ELAIC interconnection can have minimum line width in the range of 0.25 micron to 5 micron.

This approach will not only enable higher bandwidth and lower loss connectivity as compared to conventional circuit board packaging (especially critical for superconducting classical computing applications) but will also allow for multiple levels of high-density connections, since the wiring between chips is as small as the wiring within a chip.

Ultimately, the large area IC solution allows for a wide trade space—in terms of cost and partitioning—for each of the individual applications, and carves out a path towards large-scale heterogeneous fabrication. The developed approach may, for example, be used to combine trusted and commercial foundry chips to create highly secured systems in which the commercial foundry chips provide desired circuit density/performance and the trusted foundry chips add system security. The potential for mix-and-match IC schemes serves as a key advantage that provides yield enhancements, as well as power and performance benefits to many systems.

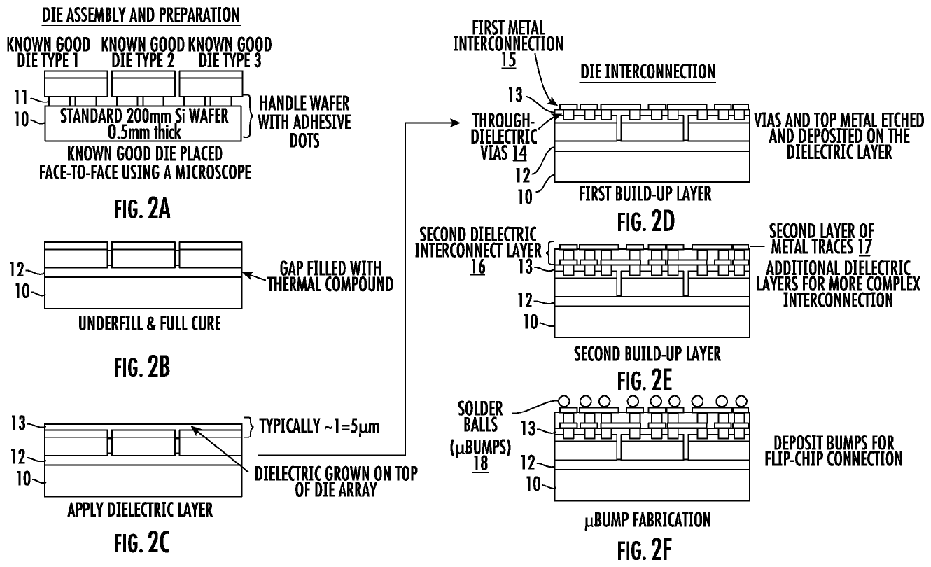

FIGS. 2A-2F show the general process to create an ELAIC. The general process has two components; the die assembly and preparation stage, and the die interconnection stage.

Generally, as shown in FIG. 2A, a plurality of known good dies, such as known good die of a first type, known good die of a second type and known good die of a third type, are disposed on a handle wafer 10. The handle wafer may be a standard 200 mm silicon substrate having a thickness of 0.75 mm. Of course, the handle wafer 10 may be different dimensions or made from a different material. Further, each die may have a semiconductor package pitch, which may be the same or different from other die. The known good dies are affixed to the handle wafer 10 using adhesive dots 11. The dies may be placed using a microscope or another precision vision system. In example, at least a portion of known good die of the first type and known good die of the second type have a gap therebetween that is in the range 0-20 micron. It also possible that at least a portion of known good die of the first type and known good die of the second type have a gap therebetween wherein the gap at the bottom surface that is different than the gap at the top surface. In one example, the bottom surface gap between known good die of the first type and known good die of the second type may be 1 micron and top surface gap between known good die of the first type and known good die of the second type may be 20 micron.

Next, as shown in FIG. 2B, an underfill is performed to fill the region between the handle wafer 10 and the known good dies. This gap fill material 12 may be a high thermally conducting compound. In one example, gap fill material may be high thermally conducting particle (such as Silver, Zinc oxide, Aluminum nitride and others) filled polymer material. In one example, polymer can be solvent less polymer. It may be a thermoset or thermoplastic polymer. In one example, adhesive dot and gap fill materials are same and/or compatible materials. The adhesive dot 11 may be interconnected and/or react and/or inter-diffused and/or inter-linked during the advancing and/or curing process of gap fill material. A first dielectric layer 13 is then grown on top of the known good dies, as shown in FIG. 2C. At this point, the assembly has been created and is ready to have the interconnections created. In one embodiment, there is a cleaning step prior to the deposition of the first dielectric layer 13. It may be chemically cleaned (such as by using RCA clean) and/or plasma cleaned and/or etched. In one example, gap fill material 12 and first dielectric layer 13 materials are the same and/or compatible materials. The gap fill material 12 may be interconnected and/or react and/or inter-diffused and/or inter-linked with the first dielectric layer 13 during the advancing and/or curing process.

Vias 14 are created in the first dielectric layer 13 to allow connection to the pads of the dies. Additionally, as shown in FIG. 2D, a first layer of metal traces 15 is deposited on the first dielectric layer 13.

This process may be repeated a number of times if desired. For example, FIG. 2E shows a second dielectric layer 16 and a second layer of metal traces 17.

Finally, as shown in FIG. 2F, solder bumps, also referred to as microbumps 18, are applied to contact points on the uppermost metal traces.

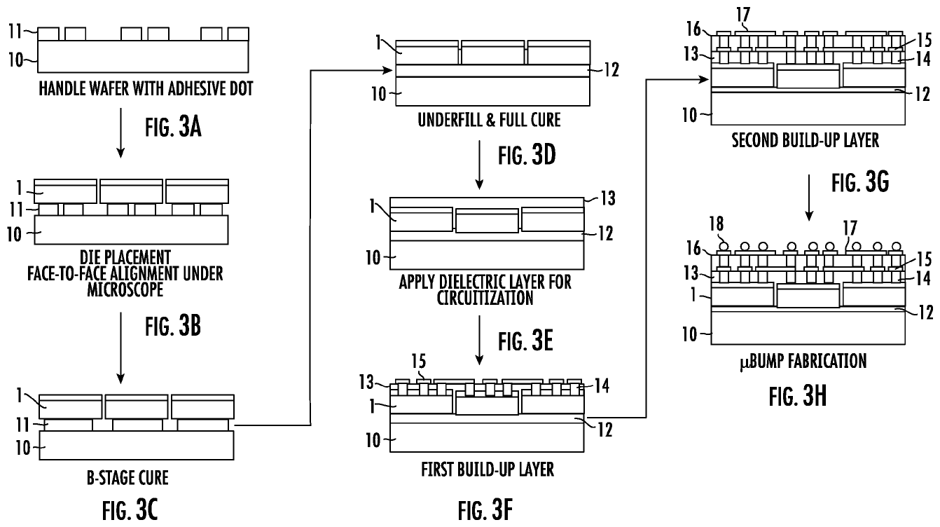

The general process used to create the ELAIC includes an assembly stage, where a plurality of known good dies is attached to a substrate, a compound is added to fill the region between the dies and the substrate and a dielectric layer is deposited on the top surface of the dies. The general process also includes an interconnection stage, where vias are created in the dielectric layers, metal traces are created in the metal layers disposed on the dielectric layers, and microbumps 18 are attached to the uppermost metal layer. This general process may be further refined. FIGS. 3A-3H, 4A-4G and FIGS. 5A-5F shows various fabrication processes that may be used.

FIGS. 3A-3H show a first representative fabrication process that may be utilized to create an ELAIC.

The process begins with a plurality of unpackaged known good integrated circuits or dies. The traditional semiconductor fabrication approach uses typical foundry process. The dies may be fabricated on 200-mm silicon wafers using a niobium and/or Al and/or Cu-based integrated-circuit fabrication process. These dies typically have multiple metal layers, each separated by PECVD silicon oxide dielectric and superconducting/normal vias used to connect the layers. The die wiring layers are typically patterned using I-line (365 nm)/EX4 (248 nm) photolithography, which supports minimum wiring layer dimensions of 0.35 μm and die sizes exceeding 20×20 mm². The dies may be configured to perform any function. For example, the dies may be heterogeneous, such that the types of functions performed by the different dies is different. Representative functions may include a processing unit, a memory, a system-on-a-chip, a network flow processor, an ASIC, a SerDes network interface, hardware accelerators, network interfaces, and others. Further, the dies may be fabricated using different technologies and processes. Additionally, the dies may have different sizes, in terms of length, width and height.

The present approach is enabled by one or more redistribution layers. As part of an on-going effort to develop new electrical interconnections between the dies and the RDL on either side of the RDL or multiple RDLs, connections can be made by a number of means. The RDLs are used to provide power, control and input/output signals between known good dies in the ELAIC.

As shown in FIG. 3A, a handle wafer 10 is utilized. The handle wafer 10 may be silicon, although other materials, such as SiGe, SiC, sapphire, copper, high thermally conductive materials and others may be used. In some embodiments, the handle wafer 10 may be high thermally conductive metal, such as copper, or an alloy or multi-metal layer stack. Adhesive dots 11 are disposed on the handle wafer 10 in those areas on which a plurality of dies 1 will be placed. In other words, the adhesive is placed in dots that correspond to the placement of the various dies 1. Next, as shown in FIG. 3B, the plurality of dies 1 are placed on the handle wafer 10. This placement may be done using a microscope or another means, such as a high precision optical system, to ensure face-to-face alignment. The plurality of dies 1 is disposed adjacent to one another. The number of dies 1 is not limited by this disclosure and may be any number greater than 2. In certain embodiments, there are at least 4 dies. In certain embodiments, the spacing between adjacent dies 1 may be less than 50 μm. In some embodiments, the spacing may be less than 20 μm. In other embodiments, the spacing may be less than 10 μm. The plurality of dies 1 may be arranged in 2 dimensions, such that some dies may have 2 or more adjacent dies. The space between adjacent dies may be referred to as an inter-die gap. In certain embodiments, the inter-die gaps may be between 1 μm and 20 μm. The plurality of dies 1 may be attached to handle wafer 10 using polymer and/or thermal interface materials. The bond line thickness between the handle wafer 10 and the plurality of dies 1 may be between 1 μm and 100 μm.

Next, as shown in FIG. 3C, the structure is partially cured. The areas between the plurality of dies 1 and the handle wafer 10 are then filled, as shown in FIG. 3D. The gap fill material 12, which comprises an epoxy, is filled into the inter-die gaps through capillary action. This may be referred to as an underfill process. The structure is then completely cured. In one example, the adhesive dot 11 may become deformed (such as between the processes shown in FIG. 3B and FIG. 3C), during B-staged and/or partial curing. In one example, partial curing at or above a predetermined temperature, such as 65° C., shows the adhesive dot having minimum or close to minimum viscosity. As an alternative, the underfill can be replaced by a thermal interface material, such as silver filled adhesive, indium preform, or titanium-gold-indium, and the gap fill material 12 may be plated copper for efficient heat dissipation. In some embodiments, the inter-die gaps may be at least partially filled with one or more of the following: polymer, a ceramic, a metal, a composite, and an alloy. In some embodiments, the inter-die gaps are at least partially filled with high thermally conductive materials. Some materials that may be used include Benzocyclobutene (BCB), Cycloaliphatic epoxy, indium thin film, silver epoxy, silica filled epoxy and siloxane materials, such as filled or unfilled or modified PDMS.

As shown in FIG. 3E, a first dielectric layer 13 is applied on top of the plurality of dies 1. The first dielectric layer 13 may be a photo-patternable materials such as BCB, polyimide or others. It is also possible to use silicon dioxide and/or a high K dielectric layer. This first dielectric layer 13 may be created using deposition such as evaporation, chemical vapor deposition (CVD), plasma enhanced CVD (PECVD), metal organic CVD (MOCVD), pulsed laser deposition (PLD), epitaxial growth, or spin and/or spray coating. This first dielectric layer 13 will be used to form electrical connections between pads on different dies.

In one embodiment, shown in FIG. 3E, the plurality of dies 1 have die like inter-die planarity. In one example, at least one section of the top surface of FIG. 3E has inter-die planarity less than 5 microns. The first dielectric layer 13 has a thickness that is greater than the inter-die planarity. For example, the thickness of the first dielectric layer 13 may be around 1-2 micron when inter-die planarity less than 1 micron. In this way, the first dielectric layer 13 may be used to create a top surface that is flat or nearly flat.

In some embodiments, chemical mechanical polishing (CMP) is used before and/or after deposition. It is also possible to use multi-layer deposition and use CMP in between layer deposition. It is further possible to use a combination of deposition techniques (PECVD+MOCVD). It is also possible that the first dielectric layer 13 is a combination of layers. In one example, it may be PECVD silicon dioxide-BCB-PECVD silicon dioxide. In some cases, alignment correction is performed before circuitization. In one embodiment, image software and/or direct write and/or laser direct image process and/or physical alignment process are used to correct for misalignment. For example, the top view image of FIG. 3E may be used to check misalignment. Software and/or manual operations correct misalignment and the digital mask create for circuitization. Each circuitization layer of an individual ELAIC may be corrected and a layer optimized digital mask may be created. Next, circuitization is performed on the structure, as shown in FIG. 3F. Holes, such as micro vias 14, are created in the first dielectric layer 13 to allow connection to the pads disposed on the dies 1. In one example, vias 14 are made using a photoimageable or photo patternable dielectric, such as Benzocyclobutene (BCB), photoimageable polyimide or others. A first layer of metal traces 15 are then applied on the top surface of the first dielectric layer 13, forming connections between pads on different dies. The first layer of metal traces 15 may be made using subtractive metal etching or lift-off process. A semi-additive approach may be used to achieve small metal feature.

It is also possible to use BCB as a photo-patternable dielectric, create the BCB pattern, deposit the first layer of metal traces 15 for interconnection and use PECVD silicon dioxide to coat the metal on top of the BCB. In this case, PECVD oxide will stay on top of the first layer of metal traces 15 and rest of the oxide will be etched with the metal.

These metal traces interconnecting two dies may have a minimum length of between 5 microns and 500 microns. These metal traces may have a minimum trace width of between 0.35 microns and 2 microns. In some embodiments, normal metal is used for the traces, while in other embodiments, superconducting metal is utilized.

The first dielectric layer 13, the vias 14 and the first layer of metal traces 15 form a first redistribution layer (RDL). Additional RDLs may be created by repeating these steps. Formation of a second RDL is shown in FIG. 3G.

A second dielectric layer 16 may then be added, as shown in FIG. 3G. The material used for the second dielectric layer 16 may be any of those described above. As described above, a second layer of metal traces 17 are then applied on the top surface of the second dielectric layer 16, forming connections between pads on different dies, or between traces on the first dielectric layer 13 and a pad of another trace. It is noted that while FIG. 3A-3H shows two dielectric layers, which are transformed into redistribution layers (RDLs), the disclosure is not limited to this number of RDLS. After the dielectric layers have been applied and circuitization has been completed, microbumps 18 may be added on the top surface of the uppermost RDL, as shown in FIG. 3H.

In some cases, the underfill, the gap fill material 12 and redistribution layers use the same materials, such as BCB. In this embodiment, the adhesive dot 11 may be made with epoxy.

Thus, the RDLs may utilize an oxide and/or photo patternable polymer based dielectric. The thickness of the dielectric layers 13, 16 may range from sub-micron to 100 microns. In certain embodiments, the redistribution layer uses PECVD silicon dioxide with dielectric thickness ranges from sub-micron to 10 microns. For photo patternable (also known as photo imageable) polymers, such as BCB, or polyimide based redistribution layers, the dielectric thickness may range from 1 micron to 100 microns. For photo patternable dielectric material, micro vias may be created to interconnect individual dies 1. Photo patternable vias create an opening on the die pad and the subsequent metal deposition creates a metallic contact to the dies through the via 14. In one example, the metal is sputtered and/or evaporated and/or plated metal layer. Photolithography is applied to the metal layer, which includes resist applied on top of metal, resist exposure and develop, metal etch and resist strip. This creates the layers of metal traces 15,17. Patterning the metal layer to make the layers of metal traces 15,17 can be done by subtractive etching. It is further possible to make the layers of metal traces 15, 17 by semi-additive process and/or modified semi-additive process.

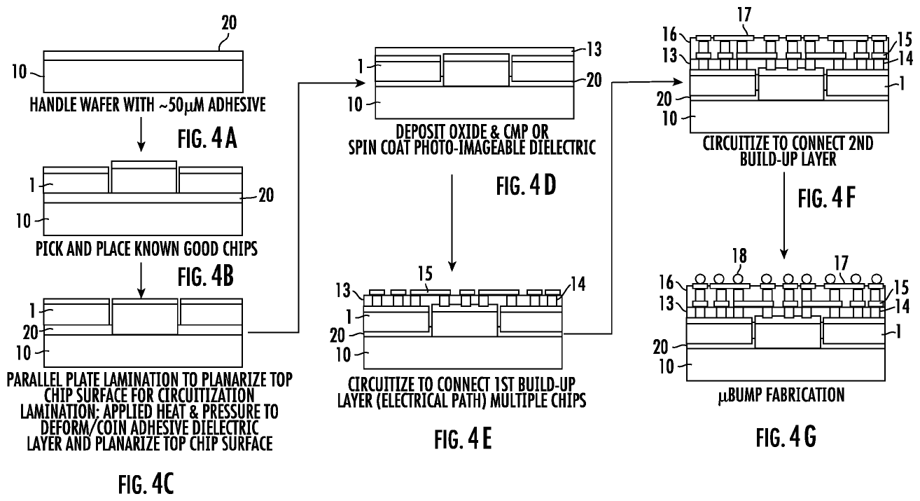

In certain embodiments, the various dies may have different heights. Various fabrication techniques may be utilized to address this. One such fabrication technique is shown in FIGS. 4A-4G. In this embodiment, a handle wafer 10 is used, as was done in FIG. 3A. However, in this embodiment, a layer of adhesive 20, which may be about 50 μm thick, is applied to the entire surface of the handle wafer 10, as shown in FIG. 4A. The plurality of dies 1 are then placed on the handle wafer 10, as shown in FIG. 4B. However, in this figure, the middle die is taller than the adjacent dies. Therefore, parallel plate lamination is used to planarize the top surface. Note that the adhesive 20 beneath the taller middle die has been compressed or displaced to allow the heights of all of the dies 1 to be the same, as shown in FIG. 4C. Although not shown, the adhesive 20 may be cured after this step. Next, a first dielectric layer 13 is formed on top of the dies 1, as shown in FIG. 4D. The dielectric may be any of those described above. This first dielectric layer 13 may be deposited or spin coated. In certain embodiments, the top surface of the first dielectric layer 13 may be planarized, such as by the use of CMP, to planarize the top surface. Thus, after completion, the plurality of dies 1 may have an inter-die planarity that is similar to that of a single die. In some embodiments, the inter-die planarity is less than 5 μm. In certain embodiments, the inter-die planarity may be less than 1 μm.

The remaining processes, shown in FIGS. 4E-4G, are similar to those shown in FIGS. 3F-3H. This includes creating vias 14 in the first dielectric layer 13 to allow connection to the pads disposed on the dies 1. A first layer of metal traces 15 is formed on the first dielectric layer 13. A second dielectric layer 16 may then be added, as shown in FIG. 4F. As described above, a second layer of metal traces 17 are then formed on the top surface of the second dielectric layer 16. Additional RDLs may be added by repeating these steps. Microbumps 18 may be added on the top surface, as shown in FIG. 4G.

Note that in both of these fabrication processes, the RDLs are created directly on the dies 1. Note that there is no interposer disposed between the dies 1 and the RDLs.

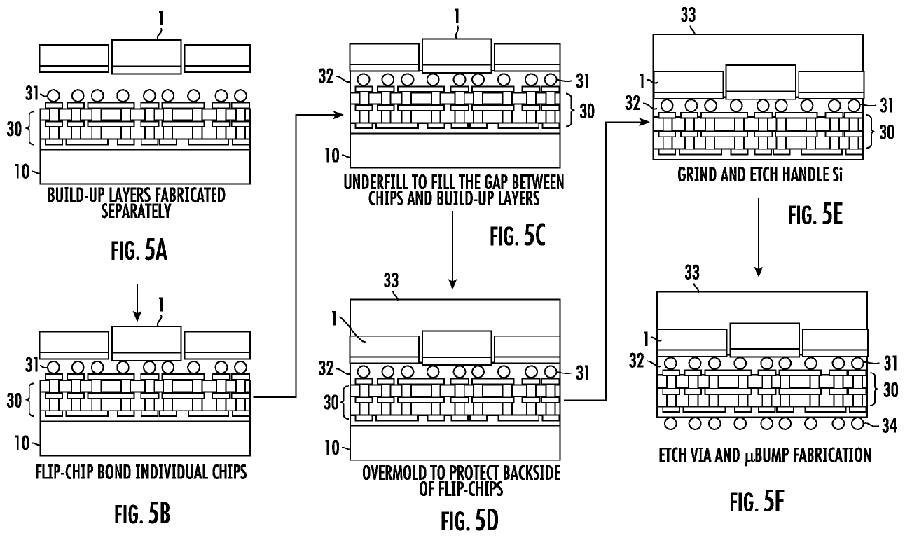

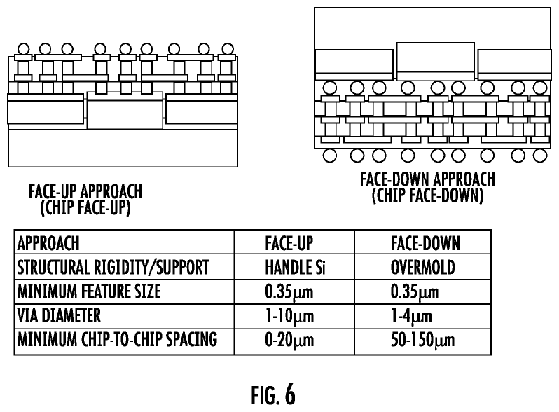

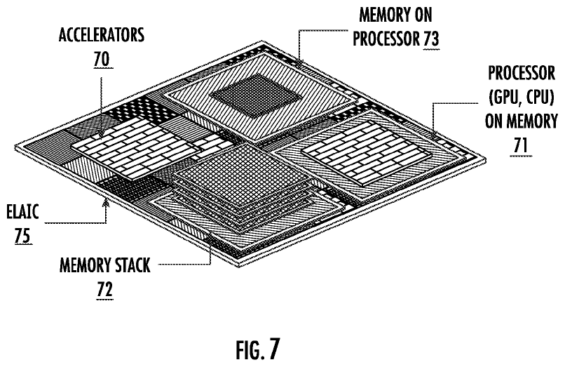

While the previous figures show the dies being placed directly on the handle wafer 10, other fabrication techniques are possible. One such approach is shown in FIGS. 5A-5F. This particular embodiment is referred to as a face-down approach, as the ELAIC is assembled by placing the die face down.

In FIG. 5A, the redistribution layers (RDLs) 30 are first deposited on the handle wafer 10. The RDLs 30 include at least a first RDL, disposed directly on the handle wafer 10, and an uppermost RDL. In one embodiment, the handle wafer 10 is a thermally and/or PVCVD Oxide coated silicon wafer. The RDLs 30 may be fabricated using the techniques described above. There may be one or more RDLs 30, and the embodiment is not limited to a particular number of RDLs. In certain embodiments, microbumps 31 are disposed on those points on the uppermost RDL that are intended to electrically connect to the dies 1.

As shown in FIG. 5B, the dies 1 are then disposed on the uppermost RDL, and are aligned such that the microbumps 31 contact their respective electrical connections on the front side of the dies 1. This is referred to as flip-chip bonding. Although micro-bump bonding between dies 1 and RDLs 30 may be used, other techniques may be used. For example, it is also possible to use oxide-oxide with metal-to-metal diffusion (instead of microbumps) bonding between dies 1 and RDLs 30. In one example, chemically active and/or self-bondable oxide are used for this oxide-oxide metal diffusion bonding.

Then, as shown in FIG. 5C, an underfill material 32 is added to fill the gaps between the RDLs 30 and the dies 1. In one embodiment, the underfill material 32 may be applied prior to attachment of the dies 1. In another embodiment, the underfill material 32 be can be applied after attachment of the dies 1. In one example, the underfill material 32 may be a solvent free liquid material, such as cycloaliphatic epoxy. In another embodiment, the underfill material 32 may be silica particle filled epoxy materials.

Next, as shown in FIG. 5D, overmolding is performed to fill the inter-die gaps and protect the back sides of the dies. The overmold 33 effectively acts as a second handle wafer. The overmold 33 may be a plastic, epoxy or other suitable material. At this point, the silicon in the original handle wafer 10 may be grinded and removed, as shown in FIG. 5E. It is possible that grinding and subsequent etching will selectively remove the silicon and stop at oxide layer of handle wafer 10. It is further possible to grind the overmold 33 to expose and subsequently thin the backside of the dies 1 for better thermalization. By removal of the silicon in the handle wafer 10 and subsequent via formation through the oxide layer, the RDL 30 may be exposed for interconnection. This allows microbumps 34 to be applied to the exposed RDL as shown in FIG. 5F. In one example, the overmold 33 may be grinded and polished to expose the backside of dies 1. In another embodiment, further polishing of the exposed dies 1 and overmold 33 to make the dies thin may be performed for efficient heat dissipation. In one embodiment, the dies 1 are polished and/or etched to remove the silicon and stop at oxide. In another embodiment, the dies 1 may have a thin layer of silicon (e.g., 10 micron) after etching Si.

FIG. 6 shows a comparison of the face up approach, shown in FIGS. 3A-3H and 4A-4G, and the face down approach, shown in FIGS. 5A-5F. Note that the face up approach relies on the handle wafer 10 for support and rigidity, while the face down approach utilizes the overmold 33 for this purpose. Note as well that the minimum feature size is equal for both approaches. The face up approach may allow for larger vias. Additionally, in some embodiments, the face down approach may allow for more RDLs than the face up approach. Finally, the face up approach may allow tighter spacing between dies than the face down approach.

In the embodiments shown above, and particularly in FIGS. 4A-4G, planarization may be important as it allows the dielectric layer to be of a minimum thickness. Various experiments were performed to demonstrate the effectiveness of this approach. Assemblies were created using 4 dies, arranged in a 2×2 array. In another experiment, assemblies were created using 16 dies, arranged in a 4×4 array. In yet another experiment, assemblies were created using 39 dies, arranged in a non-regular array. This demonstrates the ability for the ELAIC concept to scale to very large arrays.

One important issue associated with ELAIC is that of inter-die alignment. Since each die 1 is separate from the other die, an alignment process is required. In one embodiment, the dies 1 are arranged on a tape prior to be attached to the handle wafer 10. Alignment marks on the die 1, known as fiducials, may be used to determine whether there is any relative rotation between two adjacent dies 1. These fiducials can be used to correct misalignment or uneven spacing between dies. Once the dies 1 have been placed, the actual position of each die may be measured and recorded. Based on the actual placement, the traces that are used on the RDL may be adjusted so that all connections are correct.

In another embodiment, the handle wafer 10 may be created having defined regions for the various dies. For example, walls, which may be between 1 μm and 800 μm tall, may be created on the top surface of the handle wafer 10. These walls may define regions into which various dies may be disposed. In certain embodiments, the walls may be created using an etching process.

In another embodiment, cavities may be created on the top surface of the handle wafer 10. For example, a laser may be used to create cavities into which the various dies 1 are disposed.

In another embodiment, image software and/or direct write and/or laser direct image process and/or physical alignment process is used to correct for misalignment.

Thus, the present disclosure describes an extremely large area integrated circuit (ELAIC) which comprises a plurality of heterogeneous dies that are arranged as a two dimensional grid on a substrate. One or more redistribution layers (RDLs) are used to connects pads from one heterogeneous die to another die through the use of traces. Note that, in some embodiments, the traces need not connect two immediately adjacent dies. Further, traces in the RDLs are also used to provide power and ground to the dies.

Thus, in FIGS. 2-6, the ELAIC comprises at least a first and second semiconductor structure, each having first and second opposing surfaces, wherein at least a portion of one side of each semiconductor structure has a narrow gap in the range of 0 to 20 micron between the adjacent semiconductor structure. Further, the first surface of the first semiconductor structure has at least a first semiconductor package pitch. The ELAIC also includes a first high thermally conducting structure having first and second opposing surfaces, the first surface of the first high thermally conducting structure mechanically attached to the second surface of each semiconductor structure. The first surface of each semiconductor structure with the first package pitch is interconnected with at least one adjacent die.

In one embodiment, the mechanical attachment uses thermal interface materials and/or adhesive materials. In one aspect of the disclosure, the narrow gap is filled and/or partially filled with organic and/or polymer and/or ceramic and/or metal based materials. In another aspect of the disclosure, the narrow gap at the first surface is different than a gap at the second surface of semiconductor structure.

In one embodiment, the interconnection between the first surface of the first semiconductor having the first package pitch and at least one adjacent die uses a redistribution layer and/or printing and/or flip-chip-integration. The interconnection may use microvias and/or microbumps.

Further, in another aspect, the ELAIC includes multiple semiconductor structures, each having first and second opposing surfaces having at least a first semiconductor package pitch, and uses misalignment correction for interconnection by image software and/or direct write and/or laser direct image process and/or physical alignment process.

To verify this approach, representative ELAICs are fabricated and observed. The results are described below.

In one test, 10 mm×10 mm circuits were created, with different trace widths leading from one die to the other through the gap. SEM micrographs show different width traces at the intersection between the dies.

A variety of non-destructive analysis techniques were utilized for ELAIC device characterization. In particular, alignment accuracy, quality of interconnects, and parallelism after chip placements were observed. X-ray imaging was used to inspect the gap between the dies after assembly, measure die compactness and silicon density within an ELAIC. Optical images confirm that silicon density in ELAIC may achieve >99%. In one example, silicon density is defined as the combination of silicon, silicon oxide, active and/or passive circuits, and inter layer dielectric material, as compared to the entirety of the ELAIC prior to the addition of re-distribution layers. It is also possible to use SiGe (silicon-Germanium) or another type of chip substrate instead of silicon substrate. In all the cases, the ELAIC process can achieve >99% chip density. For a metal plated built-in heat-sink, chip density including metal fill may be >998. It is also possible to achieve more than 99% chip area/content for the ELAIC platform. In ELAICs that were fabricated using a face down approach, the chip density including the overmold may be >99%.

Optical microscopy was used to inspect (1) alignment accuracy and (2) mechanical damage to circuits after ELAIC fabrication. The ELAIC devices were undamaged by the fabrication process, and alignment accuracy was ±3 μm. The current alignment process uses a microscope for alignment and room temperature (RT) epoxy curing (partial or full cure) to minimize chip movement during assembly. Of course, other techniques may be used.

Confocal microscopy was used to evaluate planarity between the individual dies. The confocal data indicates that the fabrication process maintains parallelism between the dies within the top chip TTV (total thickness variation) limit of the top die. Specifically, a confocal image and height scan of selected area shows negligible gap between chips. Height scan at the gap is the same as height scan in the bulk. The height scan confirms top surface planarity between the chips after ELAIC assembly. Confocal scan is generally transparent to oxide. It is clear from the confocal scan that the height variation between the dies and within the die is similar, which supports co-planarity.

Representative SEM images of a ELAIC module assembled using stealth and regular diced chips were created. Selective area SEM micrographs show a representative example of gap between two dies as well as 4 corners of ELAIC. The smooth die edge helps the process to create minimum gap chip assembly. It is clear from SEM 4 corner image that die edges are mostly smooth and misaligned by only a few microns. SEM images show 5-10 μm gap between dies when assembled together. SEM micrograph confirms that it is possible to create very narrow gap between the dies. The SEM data indicates that the ELAIC fabrication process maintains a narrow gap, such as between 5-20 microns, between the dies.

The epoxy gap filling between the dies was also reviewed. The gap fill and die surface planarity allow the selection of a variety of dielectric material (PECVD oxide, BCB, SiNR, Polyimide, etc.) to deposit on top of ELAIC surface. The optical and SEM image confirm the spacing between dies, and the confocal image confirms co-planarity. Since SEM, Optical and Confocal microscopy cannot see through the dies and therefore cannot confirm the compactness and silicon density of ELAIC after chip assembly, the SEM, Optical and Confocal analysis was supplemented with X-ray microscopy, which confirms the gap uniformity and Si-density ELAIC.

In combination, this analysis indicates that the ELAIC fabrication process maintains high alignment accuracy; produces highly compact (>99% silicon density) chip assembly with 5-20 micron spacing between chips, and maintains parallelism between the chips.

In addition to observing and validating the physical characteristics of the ELAIC, electric tests were performed as well.

To do this, three types of devices in an ELAIC geometry were designed, fabricated and tested. These devices included snakes and combs going between the dies, daisy-chain interconnected between RDLs, and JJ (Josephson Junction) chains connecting multiple dies. Snakes and combs with a wide variety of lines and spaces are used to predict ELAIC circuit yield and scalability. As expected, longer traces show higher Room Temperature resistance. The long traces crossing multiple chips show resistance over 150 ohms.

In addition to passive daisy-chain ELAIC, interconnection between active chips containing trilayer Josephson Junctions (JJs) was also investigated for larger system applications, such as quantum processors, readout, control and amplifier chips and others. Active chips can interconnect together to create multi-die system-on-chip. These Josephson Junctions/active components may be on the same die or separate dies assembled to the ELAIC platform. In either case, a first step towards assessing the ELAIC structure with Nb/Al-AlOₓ/Nb trilayer junctions is to determine the impact of fabrication on trilayer junction performance. The addition of RDL fabrication to the junction chip may change the critical current, sub-gap voltage and other junction properties. In addition, multiple chip assembly, gap filling, planarization may affect stability and junction performance at 4K. To quantify the effects of fabrication on the trilayer junction, an ELAIC assembly was fabricated where multiple superconducting chips with tri-layer junctions are attached to a single large ELAIC. This allows the ability to determine the impact of ELAIC fabrication and to demonstrate basic desirable functionalities for multi-die SoC.

To assess the electrical performance of the chip assembly, multiple 4 chip ELAICs were attached to a circuit card and wire bonded to measure I-V characteristics of trilayer-based Josephson junctions at 4.2 K. ELAIC assembled superconducting chips had multiple sizes of junctions ranging in size from 500 nm to 1500 nm. Each measured junction showed a typical I-V characteristic of Nb/Al-AlOₓ/Nb unshunted tunnel junctions such as Josephson critical current, subgap voltage, normal resistance (Rn), etc. at 4.2 K. A variety of active superconducting chips having trilayer junctions were assembled to the ELAIC. The I-V characteristics and switching current of various trilayer flip-chip JJ arrays were measured. Many ELAIC JJ arrays ranging from 40 to 20,000 JJs in series were measured, with JJ drawn diameters ranging between 1.0 μm and 0.7 μm. I-V characteristics of ELAIC JJ arrays connected multiple chips through RDL.

This system and method have many advantages.

There are several major benefits and considerable added value that heterogeneous ELAIC integration can bring, from smaller form factors, higher performance, and faster time to markets, to lower cost and increased flexibility. Due to these benefits, application of ELAIC has expanded into various applications across several market segments. ELAIC can be used in sensing and MEMS modules, for logic and memory integration, in RF and FEM modules, in wireless connectivity packages and power management systems, with applications in mobile, IoT, automotive, healthcare, high performance computing and data centers as well as aerospace and defense market segments.

The ELAIC platform allows further integration. FIG. 7 shows an example of integration where an entire computer system is integrated using an ELAIC. The system includes accelerators 70, processors 71, memory 72 and memory stacks 73, all disposed on a ELAIC platform 75. In this embodiment, the ELAIC platform 75 comprises multiple dies at the bottom of a 3D-stack. This kind of 3D-stack may be used for active-to-active bonding. Active-to-active bonding, where both sides utilize efficient metallic thermal interface materials (TIM), reduce die-die thermal resistance, and thermal cross-talk between neighboring die, and provide higher power density with a thermally efficient silicon floor plan. FIG. 7 represents heterogeneous ELAIC integration with an active and/or passive interposers with through-silicon vias (TSVs) and active-to-active bonding with shorter interconnect length for chip-to-chip communication support of high-bandwidth, low-latency communication. FIG. 7 represents an example of high-performance computing to adapt smaller and more diverse technology nodes suitable for the artificial intelligence (AI), machine learning, and embedded computing platforms, as these applications consistently involve trade-offs between enabling more compute capability versus constraints in volume, weight, power, and thermal management. The architecture shown in FIG. 7 supports efficient computing with relatively lower power consumption. The architecture may be used to create a multi-die SoC or a multiprocessor SoC (MPSOC). For high-performance computing (HPC), power consumption comes primarily from moving data between chips in a system rather than from the on-chip computing operations. The architecture of FIG. 7 reduces data movement constraints by integrating multiple chiplets with minimum chip-to-chip spacing in 2D as well as in 3D space, thus reducing the loading of these I/O paths by at least an order of magnitude.

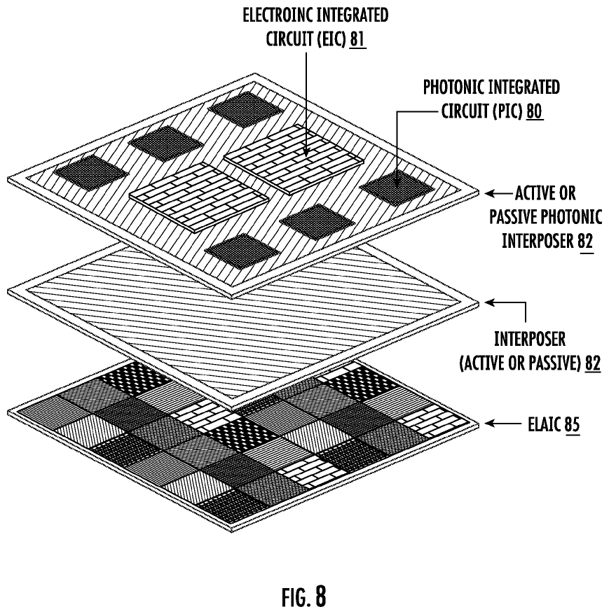

FIG. 8 shows an example of 3D integration with ELAIC, where photonic integrated circuits (PICs) 80 and electronic Integrated Circuits (EICs) 81 are connected through single or multiple active and/or passive photonic interposer 82. In one example, one or more of the interposers may be a circuitized substrate. The ELAIC 85 may be connected to the PICs 80 and EICs 81 using microbumps. Micro-bump bonding may be used between ELAIC 85 to the PICs 80 and EICs 81 and interposer 82. However, it is also possible to use oxide-oxide with metal-to-metal diffusion (instead of microbumps) bonding between these devices. In one example, interposers 82 may use self-bondable oxide for this oxide-oxide metal diffusion bonding.

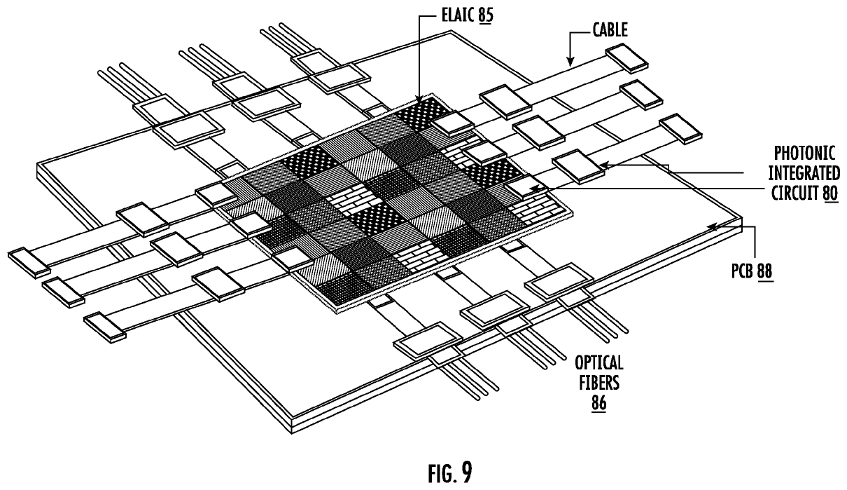

The photonic interposer 82 and/or the PIC 80 may be attached to optical fibers 86, as shown in FIG. 9. FIG. 9 shows a top view of ELAIC packaging. In one example, PIC 80 may be bonded to printed circuit board (PCB) 88 as well as ELAIC platform 85. In one example, the PIC 80 is bonded to the ELAIC platform 85 and the PCB 88 using bumps. In one example, the PCB 88 may be a circuitized substrate. It is possible that the bump pitch on the ELAIC side and PCB side are different. For example, the bump pitch for the ELAIC may be 50 microns and the bump pitch for the PCB may be 500 micron. In one example, the PIC 80 may have same size bump but use multiple bumps per pad for the PCB 88. Alternatively, the ELAIC platform 85 may use multiple bumps per pad.

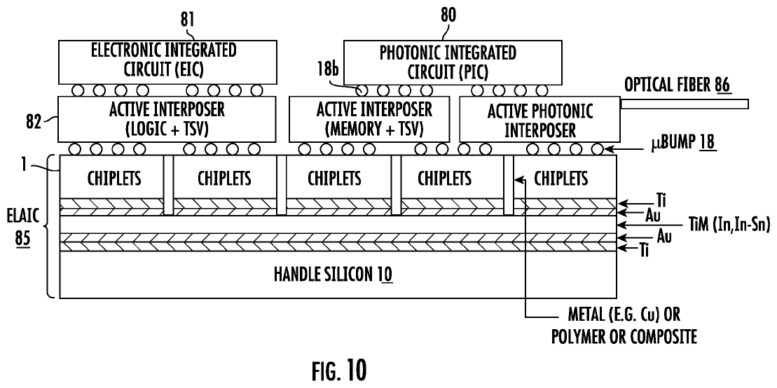

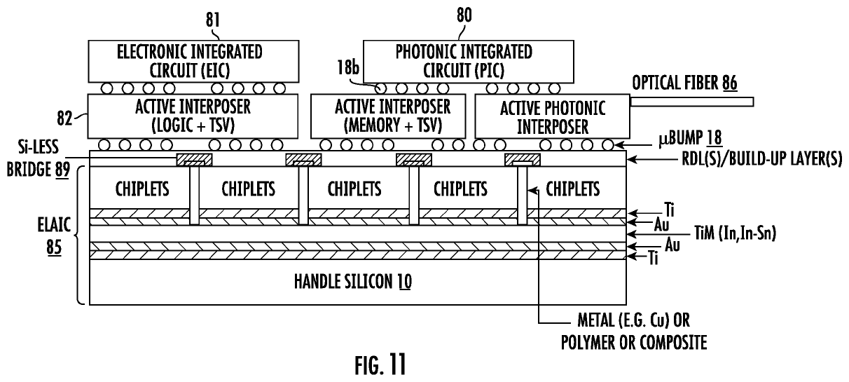

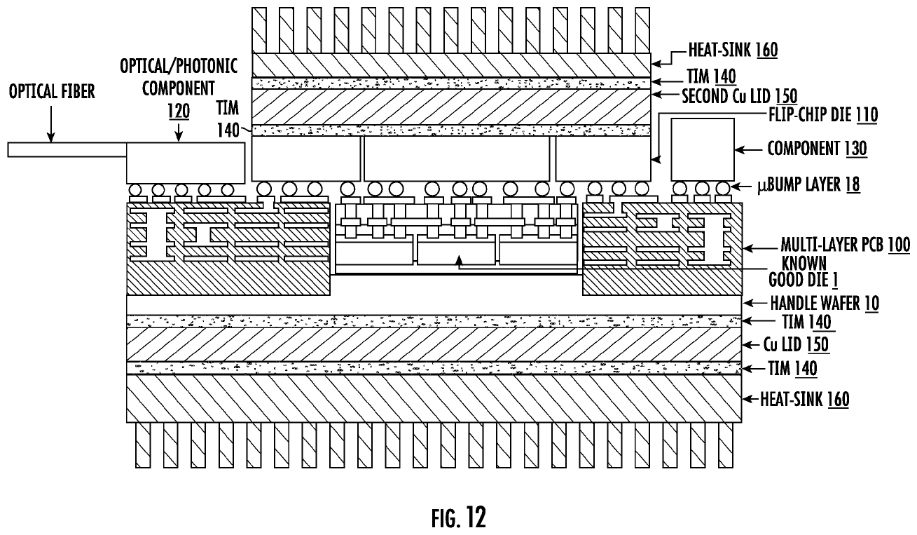

ELAIC may integrate separately manufactured components with high density interconnects to achieve enhanced functionality and improved performance. FIGS. 10 and 11 show a cross-section of a 3D-ELAIC that may be used to integrate photonic circuits with other devices.

FIG. 10 shows a ELAIC 85, where the known good dies 1 are arranged so that the pads are facing away from the handle wafer 1. In this embodiment, the microbumps 18 are used to connect the ELAIC 85 to interposers 82. The interposers 82 may be active interposers which include logic, memory and photonics. Additionally, the interposers 82 may include through silicon vias (TSVs). Additional microbumps 18b are used to electrically and physically connect the interposers 82 to the EIC 81 and PIC 80. In this embodiment, the interposer 82 may include the RDLs, and the ELAIC platform 85 is interconnected (bump bonded and/or oxide-oxide bonded) with the RDLs from the interposer 82. Additionally, in this embodiment, to improve thermal dissipation, various layers may be disposed between the handle wafer 10 and the known good dies 1. For example, layers of titanium, gold, and/or thermal interface material (such as indium or indium tin) may be disposed between these components. Further, a thermally conductive material, such as metal, polymer or a composite, may be used as the gap fill material. FIG. 10 also represents memory sharing between the chiplets of the ELAIC platform 85. In one example, the chiplets of the ELAIC platform 85 may be CPUs and/or GPUs and/or accelerators, which share a common memory (e.g., SRAM, DRAM, NOR, NAND) platform with minimum interconnect length for high bandwidth and low latency communication. In one example, memory interconnect pitch is different for different chiplets of ELAIC 85. In one example, the interposers 82 use oxide-oxide bonding to interconnect the EIC 81 and/or PIC 80. It is further possible to use via first or via last approach for interconnection between the interposers 82 and EIC 81 and/or PIC 80.

FIG. 11 shows 3D-ELAIC stacking where multiple known good dies 1 from the ELAIC platform 85 may be interconnected through the microbumps of a flip-chip die which is also known as “Si-less bridge” 89 because it creates an interconnect bridge between two or more chiplets of the ELAIC platform 85. In this embodiment, RDLs are used to electrically connects pads from the known good dies 1 to one another and to also create contact points for the microbumps 18. As described above, interposers 82 may be electrically connected to the microbumps 18. Further, a second set of microbumps 18b are used to electrically and physically connect the interposers 82 to the EIC 81 and PIC 80. In one embodiment, the ELAIC platform 85 may be used without RDLs. In this embodiment, a Si-less bridge 89 with a height of 2-8 micron may be used for interconnection bridge between two or more neighboring chiplets. Interposer 82 may be directly bonded to the ELAIC platform 85 without RDLs using bumps. In this embodiment, the post bond bump height will be larger than the height of the Si-less bridge 89. In one example, 50 micron tall bump may be used to connect chiplets with interposer 82. In this embodiment, the interposer 82 serves as the RDL. In one example, the bump can be a c4 (controlled collapse chip connection) and/or BGA (ball grid array) type connection where the Si-less bridge height is less than the bonded c4 and BGA height. In one embodiment, the Si-less bridge 89 may use through oxide via (TOV) to interconnect the interposer 82.

FIG. 12 shows 3D-ELAIC packaging wherein heat sinks are applied to the system. The ELAIC platform 85 includes a handle wafer 10, known good dies 1 and RDLs as described above. Additionally, one or more multilayer printed circuit boards 100 may also be affixed to the handle wafer 10. Microbumps 18 are used to connect the known good dies 1 and the PCBs 100 to one or more flip-chip die 110, optical/photonic components 120 and other components 130. A thermal interface material (TIM) 140 may be disposed between the handle wafer 10 and a copper lid 150. Another TIM 140 may be disposed between the copper lid 150 and the heat sink 160. Additionally, the flip-chip die 110 may also provide added functionality to the computing module. In one example, the flip-chip die 110 may be memory and/or CPU and/or GPU and/or Accelerator. TIM 140 is applied to the exposed surface of the flip-chip dies 110 and a second copper lid 150 is affixed to the flip-chip dies 110. Another layer of TIM 140 may then be applied and a heat sink 160 may be applied to the second copper lid 150. In one example, FIG. 12 represent a computing module with efficient heat dissipation from both sides. In one example, the bump pitch of the ELAIC and PCB side of the flip-chip die 110 are different. For example, bump pitch for the ELAIC could be 50 micron and the bump pitch for the PCB could be 500 micron. In one example, flip-chip die 110 may have same size bump but use multiple bumps per pad for PCB. Further, the ELAIC 85 can use multiple bumps per pad.

The ELAIC platform allows for many possible configurations.

For example, the ELAIC platform allows a semiconductor structure to be disposed on top of two other semiconductor structures. For example, a third semiconductor structure may be disposed on top of a first semiconductor structure and a second semiconductor structure. In this embodiment, the ELAIC platform includes a first semiconductor structure and a second semiconductor structure, each having first and second opposing surfaces, and also a third semiconductor structure having first and second opposing surfaces, the second surface of the third semiconductor structure having a third semiconductor package pitch. The second surface of the third semiconductor structure with the third semiconductor package pitch is interconnected with the first surface of the first semiconductor structure which has the first semiconductor package pitch and the first surface of the second semiconductor structure which has a second semiconductor package pitch. In another embodiment, the third semiconductor structure creates an interconnect bridge at least between first and second semiconductor. In one aspect, the third semiconductor structure comprises a silicon less bridge between at least the first and second semiconductor structures. The first, second and third semiconductor package pitch may be the same or different.

In another embodiment, the ELAIC platform allow an additional semiconductor structure to be disposed on top of the first and second semiconductor structures. In this embodiment, the ELAIC platform also includes a fourth semiconductor structure having first and second opposing surfaces, the second surface of the fourth semiconductor structure having a fourth semiconductor package pitch. The second surface of the fourth semiconductor structure having a fourth package is semiconductor pitch interconnected with the first surface of the first semiconductor structure having a first semiconductor package pitch and the first surface of the second semiconductor structure having a second semiconductor package pitch. In another embodiment, the combined interconnect height between the fourth and first semiconductor structures is the same or higher than the silicon less bridge between first and second semiconductor structures.

Further, other embodiments are also possible. For example, an ELAIC platform may include at least four semiconductor structures, each having four sides and first and second opposing surfaces. In this embodiment, the ELAIC platform includes a multi-layer semiconductor having first and second opposing surfaces, the first surface of a first semiconductor structure having at least a first semiconductor package pitch. The ELAIC also includes a second semiconductor structure having first and second opposing surfaces, the first surface of the second semiconductor structure having a second semiconductor package pitch. The ELAIC additionally includes a third semiconductor structure having first and second opposing surfaces, the first surface of the third semiconductor structure having a third semiconductor package pitch. The ELAIC additionally includes a fourth semiconductor structure having first and second opposing surfaces, the first surface of the fourth semiconductor structure having a fourth semiconductor package pitch. Each of these semiconductor structures has four sides, and the surfaces of each semiconductor structure has four regions, each region proximate a respective side. As shown in the top left corner of FIG. 1B, there are four semiconductor structures, which in that figure are defined as: the first semiconductor structure is a RF system, the second semiconductor structure is a power management IC, the third semiconductor device is a CPU and the fourth semiconductor structure is a transceiver. Each of these semiconductor structures is interconnected to its two adjacent neighbors. Thus, the first region of the first surface of the first semiconductor structure may be interconnected with the third region of the first surface of second semiconductor structure. Similarly, the second region of the first surface of the first semiconductor structure is interconnected with the fourth region of the first surface of fourth semiconductor. Additionally, the fourth region of the first surface of the third semiconductor structure is interconnected with the second region of the first surface of the second semiconductor structure. Similarly, the third region of the first surface of the third semiconductor structure is interconnected with first region of the first surface of the fourth semiconductor. At least one portion of one interconnection will have very narrow gap in the range of zero to twenty micron. The interconnection may use redistribution layers and/or printing and/or flip-chip-integration. The interconnection may also include microvias and/or microbumps.

In some embodiments, the ELAIC platform further includes first interconnect structures disposed between the semiconductor structures. These first structures be interconnect may interposers, which may be passive or active. Alternatively, these first interconnect structures may be RDLs. Thus, in one embodiment, the ELAIC platform includes one or more first interconnect structures disposed between and coupled to selected portions of the first surface of the second semiconductor structure and to selected portions of the first surface of the first semiconductor structure. The first interconnect structures form an interconnect for electrically and coupling mechanically the second semiconductor structure to the first semiconductor structure. In certain embodiments, the first interconnect structures couple the first region of the first surface of the first semiconductor structure and the third region of the first surface of the second semiconductor structure. Each of the first interconnect structures has first and second opposing portions. A distance between the first and second portions is selected based upon at least one of the first semiconductor package pitch and the second semiconductor package pitch.

In another embodiments, the ELAIC platform is configured so that the first semiconductor structure having at least a first semiconductor package pitch is interconnected with at least second semiconductor structure having a second semiconductor package pitch.

In certain embodiments, the ELAIC platform additionally includes one or more second interconnect structures disposed between and coupled to selected portions of the first surface of the third semiconductor structure and to selected portions of the first surface of the second semiconductor structure. The second interconnect structures form an interconnect for electrically and mechanically coupling the third semiconductor structure to the second semiconductor structure. In certain embodiments, the second interconnect structures couple the fourth region of the first surface of the third semiconductor structure and the second region of the first surface of the second semiconductor structure. Each of the second interconnect structures has first and second opposing portions. A distance between the first and second portions is selected based upon at least one of the second semiconductor package pitch and the third semiconductor package pitch. The first and second interconnect structures are selected such that second semiconductor structure is provided on a same package level of the multi-layer semiconductor device as the third semiconductor structure.

The ELAIC may include one or more of the following features individually or in combination with other features. The first semiconductor structure may be an interposer module or a multi-chip module (MCM). In some embodiments, at least one of the first interconnect structures includes a first portion coupled to the first surface of first semiconductor structure. In some embodiments, the first portion of the first interconnect structure includes a first interconnect pad having first and second opposing surfaces, the first surface of the first interconnect pad corresponding to the first portion of the at least one of the first interconnect structures. The first portion may also include a first conductive structure having first and second opposing portions. The first portion of first conductive structure may be disposed over and coupled to the second surface of the first interconnect pad.

In some embodiments, at least one of the first interconnect structures includes a second portion coupled to the first surface of second semiconductor structure. The second portion includes a second interconnect pad having first and second opposing surfaces, the first surface of the first interconnect pad corresponding to the second portion of the at least one of the first interconnect structures. The second portion also includes a second conductive structure having first and second opposing portions, the first portion disposed over and coupled to the second surface of the second interconnect pad.

In some embodiments, the ELAIC platform includes an under bump metallization (UBM) layer or structure disposed between a first surface of a second conductive structure and a second surface of a second interconnect pad. The UBM layer or structure is provided from a fusible conductive material having a melt temperature. The first interconnect structures include at least one interconnect structure provided as an Indium (In) and/or Tin and/or tin-lead (Sn—Pb) and/or tin-silver-copper and/or tin-silver micro-bump. The first interconnect structures also include at least one interconnect structure provided as a Gold (Au) and/or Copper micro-bump. The second semiconductor structure may be coupled to the first semiconductor structure using a flip-chip bonding process. The at least one interconnect structure provided as a Gold (Au) and/or Copper micro-bump controls the distance between the first and second portions of the at least one interconnect structure provided as an Indium (In) and/or Tin and/or tin-lead (Sn—Pb) and/or tin-silver-copper and/or tin-silver micro-bump during the flip-chip bonding process.

Further, methods of fabricating the ELAIC platform are defined. For example, a method for fabricating the ELAIC includes providing a first semiconductor structure having first and second opposing surfaces, the first surface of the first semiconductor structure having at least a first semiconductor package pitch. The method also includes providing a second semiconductor structure having first and second opposing surfaces, the first surface of second semiconductor structure having second semiconductor package pitch. The method additionally includes providing a third semiconductor structure having first and second opposing surfaces, the first surface of third semiconductor structure having a third semiconductor package pitch which is different from at least the second semiconductor package pitch. The method further includes providing a fourth semiconductor structure having first and second opposing surfaces, the first surface of fourth semiconductor structure having a fourth semiconductor package pitch which is different from at least the second semiconductor package pitch. Each semiconductor structure has four sides and at least one section of one side of at least one semiconductor has a gap in the range of 0-20 micron between the adjacent semiconductor structure. For example, first side of first semiconductor structure may be adjacent to third side of second semiconductor structure. Similarly, second side of first semiconductor structure may be adjacent to the fourth side of the fourth semiconductor structure. Additionally, the fourth side of third semiconductor structure may be adjacent to second side of second semiconductor structure. Similarly, the third side of third semiconductor structure may be adjacent to first side of fourth semiconductor structure.

The method further includes providing one or more first interconnect structures using redistribution layer and/or printing. Each of the first interconnect structures has first and second opposing portions. A distance between the first and second portions is selected based upon at least one of the gap between adjacent semiconductor sides. The method also includes disposing the first portions of the first interconnect structures over selected portions of the first surface of the first semiconductor structure. The method includes coupling selected portions of the first surface of the second semiconductor structure to the selected portions of the first surface of the first semiconductor structure to form an interconnect for electrically and mechanically coupling the second semiconductor structure to the first semiconductor structure. The method additionally includes coupling the selected portions of the first surface of the fourth semiconductor structure to the first surface of the first semiconductor structure to form an interconnect for electrically and mechanically coupling the first semiconductor structure to the fourth semiconductor structure. Furthermore, the method additionally includes coupling selected portions of the first surface of the third semiconductor structure to the first surface of the second semiconductor structure to form an interconnect for electrically and mechanically coupling the third semiconductor structure to the second semiconductor structure. The method also includes coupling selected portions of the first surface of the fourth semiconductor structure to the first surface of the third semiconductor structure to form an interconnect for electrically and mechanically coupling the fourth semiconductor structure to the third semiconductor structure.

The method also includes providing one or more second interconnect structures. Each of the second interconnect structures has first and second opposing portions. A distance between the first and second portions is selected based on at least one of the first semiconductor package pitch and the second and/or forth semiconductor package pitch. Similarly, a distance between the first and second portions is selected based upon at least one of the third semiconductor package pitch and the second and/or forth semiconductor package pitch.

The method additionally includes disposing the first portions of the first interconnect structures over selected second portions of the first surface of the second semiconductor structure. The method further includes coupling the selected portions of the first surface of the third semiconductor structure to the second portions of the third interconnect structures to form an interconnect for electrically and mechanically coupling the third semiconductor structure to the second semiconductor structure. The interconnect is provided on the first package level of the ELAIC device.

The method may include one or more of the following features either individually or in combination with other features. For example, a fourth semiconductor structure having first and second opposing surfaces may be provided. The first surface of fourth semiconductor structure has a fourth semiconductor package pitch which is different from at least one of the second semiconductor package pitch and the third semiconductor package pitch. The method may also include providing one or more third interconnect structures. Each of the third interconnect structures has first and second opposing portions. A distance between the first and second portions of the third interconnect structures is selected based upon at least one of the first semiconductor package pitch and the fourth semiconductor package pitch. In some embodiments, the first portions of the first interconnect structures are disposed over selected portions of the first surface of the first semiconductor structure. In some embodiments, the method includes coupling selected portions of the first surface of the fourth semiconductor structure to the second portions of the third interconnect structures to form an interconnect for electrically and mechanically coupling the fourth semiconductor structure to the first semiconductor structure. The interconnect is provided on the first package level of the multi-layer semiconductor ELAIC device.

The 3D ELAIC architecture can provide aggressive interconnect pitch scaling for true silicon process node inter-changeability, making it possible to create high efficiency power delivery network, with a built-in heatsink to provide a better thermal solution for large chip arrays for thermally optimized Si floorplan. This architecture is suitable for power, performance and cost benefit with chip-like silicon density (Si/mm³). Active-to-active bonding with both sides using efficient metallic thermal interface materials will reduce die-die thermal resistance, thermal cross-talk between neighboring die, and allow a higher power density with a thermally efficient silicon floor plan. ELAIC's parallel interface offers even more flexibility by linking chiplets next to each connecting other, chiplets stacked vertically, and providing power to the top die in a stack directly through built-in copper heat-sinks and copper Pillars. These copper heatsinks are useful for minimizing resistance and improving power delivery. The freedom to connect dies in any direction and stack larger tiles on top of smaller ones gives a chip manufacturer much-needed flexibility in layout.

Thus, the ELAIC may be used to connect a plurality of heterogeneous die, which may be semiconductors, superconductors, electronic integrated and/or circuits photonic integrated circuits. Furthermore, inter-die communications may utilize electrical and/or optical and/or photonic connection and/or micro bumps bonded die.

Further, the ELAIC offers a number of advantages over conventional SoC approaches:
Provide various low cost chip assembly for high performance systems
ELAIC can integrate separately manufactured components with high density interconnects to achieve enhanced functionality and improved performance.
Possible to create thermally optimized silicon floorplan.
Cost benefit for yield and node optimization

TABLE 1

| System | Single Chip/SoC | ELAIC |
|---|---|---|
| Si chip content | All (100%) Si | >99% Si |
| Interconnection | Through the wafer process | Through RDL |
| System-on-chip | Monolithic SoC | Multi-die SoC |
| Technology node | Single node homogeneous | Multi node |
| | system | heterogeneous system |

Table 1 shows that the ELAIC has comparable Si chip density but is a cost-effective solution by using known good chips. The ELAIC also provides design flexibility to select chips from any foundry process to incorporate into the final system.

In addition, the ELAIC may offer the following benefits:
ELAIC technology is able to match functionality of a monolithic SoC
Able to provide aggressive interconnect pitch scaling for true silicon process node inter-changeability.
Possible to create high efficiency power delivery network.
Built-in heatsink to provide better thermal solution for large chip.
Better performance due to more Si/mm³ (Chip like Si density)
New work load: specialized requirements (e.g., AI)
Active-to-active bonding, both side efficient metallic thermal interface materials (TIM1), reduce die-die thermal resistance, thermal cross-talk between neighboring die, higher power density with a thermally efficient Si floor plan.
ELAIC with short (50-500 μm) chip-to-chip communication links reduce latency, increase bandwidth, and reduce energy/bit cost.
ELAIC with short (50-500 μm) chip-to-chip communication links can eliminate SerDes by using parallel I/O. SerDes (serialization & deserialization) occupy significant portion of die, consume up to 30% of total chip power. SerDes use high speed transmitter and receiver circuit to maintain signal integrity over long data links. Thus, the inter-die communications may use parallel input/output connection and/or SerDes and/or low power high speed transmitters and/or receiver circuits.
ELAIC with short wire-lengths (50-500 μm) have excellent signal transfer characteristics with low channel loss and low cross-talk. With fine interconnect pitches (5-35 μm), the ELAIC can achieve significant size, weight, power and performance benefit.
ELAIC can act as a multi-die ASIC which contains a large local memory buffer (i.e., cache) to reduce the number of off-chip memory transactions. The Multi-Die ASIC can be 3D integrated with DRAM or SRAM with 50 μm wiring length effectively eliminates the capacitive load, which reduces the capacitive switching power more than 90%. Further bandwidth and power efficiency improvements can be achieved with specifically designed interfaces for 3D integration to a large external memory (SRAM or DRAM).

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1-46. (canceled)

47. A multi-layer semiconductor device, comprising:
a first semiconductor structure, having four sides with first and second opposing surfaces, wherein each surface comprises four regions, each proximate to a respective side, the first surface of a first semiconductor structure having at least a first semiconductor package pitch;
a second semiconductor structure having four sides with first and second opposing surfaces, wherein each surface comprises four regions, each proximate to a respective side, the first surface of the second semiconductor structure having a second semiconductor package pitch;
a third semiconductor structure having four sides with first and second opposing surfaces, wherein each surface comprises four regions, each proximate to a respective side, the first surface of the third semiconductor structure having a third semiconductor package pitch; and
a fourth semiconductor structure having four sides with first and second opposing surfaces, wherein each surface comprises four regions, each proximate to a respective side, the first surface of the fourth semiconductor structure having a fourth semiconductor package pitch;
wherein a first region of the first surface of the first semiconductor structure is interconnected with a third region of the first surface of the second semiconductor structure, a second region of the first surface of the first semiconductor structure is interconnected with a fourth region of the first surface of the fourth semiconductor structure, a fourth region of the first surface of the third semiconductor structure is interconnected with a second region of the first surface of the second semiconductor structure, and a third region of the first surface of the third semiconductor structure is interconnected with a first region of the first surface of the fourth semiconductor structure.

48. The multi-layer semiconductor device of claim 47, wherein at least one portion of one interconnection comprises very narrow gap of zero to twenty micron.

49. The multi-layer semiconductor device of claim 47, wherein an interconnection utilizes redistribution layers and/or printing and/or flip-chip-integration.

50. The multi-layer semiconductor device of claim 49, wherein the interconnection comprises microvias and/or microbumps.

51. The multi-layer semiconductor device of claim 47, further comprising first interconnect structures, wherein the first interconnect structures form an interconnect for electrically and mechanically coupling the second semiconductor structure to the first semiconductor structure.

52. The multi-layer semiconductor device of claim 51, wherein each of the first interconnect structures has first and second opposing portions.

53. The multi-layer semiconductor device of claim 52, wherein a distance between the first and second portions is selected based upon at least one of the first semiconductor package pitch and the second semiconductor package pitch.

54. The multi-layer semiconductor device of claim 51, further comprising one or more second interconnect structures disposed between and coupled to selected portions of the first surface of the third semiconductor structure and to selected portions of the first surface of the second semiconductor structure; wherein the second interconnect structures form an interconnect for electrically and mechanically coupling the third semiconductor structure to the second semiconductor structure.

55. The multi-layer semiconductor device of claim 54, wherein each of the second interconnect structures has first and second opposing portions.

56. The multi-layer semiconductor device of claim 55, wherein a distance between the first and second portions is selected based upon at least one of the second semiconductor package pitch and the third semiconductor package pitch.

57. The multi-layer semiconductor device of claim 56, wherein the first and second interconnect structures are selected such that second semiconductor structure is provided on a same package level of the multi-layer semiconductor device as the third semiconductor structure.

58. The multi-layer semiconductor device of claim 51, wherein the first semiconductor structure is an interposer module or a multi-chip module (MCM).

59. The multi-layer semiconductor device of claim 51, wherein at least one of the first interconnect structures comprises a first interconnect structure portion coupled to the first surface of the first semiconductor structure.

60. The multi-layer semiconductor device of claim 59, wherein a first portion of the first interconnect structure comprises a first interconnect pad having first and second opposing surfaces, the first surface of the first interconnect pad corresponding to the first portion of the at least one of the first interconnect structures.

61. The multi-layer semiconductor device of claim 60, wherein the first portion of the first interconnect structure comprises a first conductive structure having first and second opposing portions, wherein the first portion of the first conductive structure is disposed over and coupled to the second surface of the first interconnect pad.

62. The multi-layer semiconductor device of claim 60, wherein at least one of the first interconnect structures comprises a second portion coupled to the first surface of the second semiconductor structure.

63. The multi-layer semiconductor device of claim 62, wherein the second portion comprises a second interconnect pad having first and second opposing surfaces, the first surface of the first interconnect pad corresponding to the second portion of the at least one of the first interconnect structures.

64. The multi-layer semiconductor device of claim 63, wherein the second portion comprises a second conductive structure having first and second opposing portions, the first portion disposed over and coupled to the second surface of the second interconnect pad.
